(19) United States
(12) Patent Application Publication
(10) Pub. No.: US 2007/0042548 A1
(43) Pub. Date: Feb. 22, 2007

(54) Methods of forming floating gates in non-volatile memory devices including alternating layers of amorphous silicon and ALD dopant layers and floating gates so formed

(76) Inventors: Jin-Tae Noh, Gyeonggi-do (KR); Ki-Hyun Hwang, Gyeonggi-do (KR); Jae-Young Ahn, Gyeonggi-do (KR); Jin-Gyun Kim, Gyeonggi-do (KR); Sang-Ryol Yang, Gyeonggi-do (KR)

Correspondence Address: MYERS BIGEL SIBLEY & SAJOVEC, PO BOX 37428, RALEIGH, NC, 27627, US

(21) Appl. No.: 11/496,177

(22) Filed: Jul. 31, 2006

(30) Foreign Application Priority Data
Aug. 19, 2005 (KR) 10-2005-0076165

(51) Int. Cl. H01L 21/336; H01L 21/3205

(52) U.S. Cl. 438/257; 438/264; 438/593

(57) ABSTRACT

A method of forming a silicon layer on a substrate includes providing a silicon source gas to form an amorphous silicon layer on a substrate and providing a dopant source gas to adsorb dopants onto the amorphous silicon layer to form a dopant layer on a surface of the amorphous silicon layer. Related floating gates are also disclosed.

### CROSS-REFERENCES TO RELATED APPLICATIONS

This application claims priority under 35 U.S.C. § 119 to Korean Patent Application No. 2005-076165, filed on Aug. 19, 2005, the contents of which are incorporated by reference in their entirety.

### FIELD OF THE INVENTION

The present invention relates to methods of forming non-volatile memory devices, and more particularly, to methods of forming floating gates in non-volatile memory devices.

### BACKGROUND

In general, semiconductor memory devices can be classified into random access memory (RAM) devices, such as a dynamic random access memory (DRAM) or a static random access memory (SRAM), and read only memory (ROM) devices. The RAM device, which is a type of volatile memory device, has a relatively high speed of operation and is characterized in that storage data is erased when the power to the device is turned off. In contrast, the ROM device, which is a type of non-volatile memory device, has a relatively slow speed of operation and is characterized in that storage data are maintained even though the power to the device is turned off. Among the above ROM devices, an electrically erasable and programmable ROM (EEPROM) and a flash memory have been widely used for temporary data storage since storage data are electrically erased and programmed from/into the EEPROM.

In general, the above flash memory includes a vertically stacked gate structure on a semiconductor substrate in a unit cell. The stacked gate structure also includes a floating gate on the substrate, at least one tunnel dielectric layer or a dielectric interlayer and a control gate on or around the floating gate.

The flash memory cell is usually classified into a NAND type and a NOR type in view of its circuit structure. In the NAND-type flash memory device, cell transistors are connected to each other in series to thereby form a unit string, and the unit strings are connected to each other in parallel between a bit line and a ground line. In the NOR-type flash memory device, each of the cell transistors is connected to one another in parallel between the bit line and the ground line. The NOR-type may be advantageous for a high speed of operation whereas the NAND-type may be advantageous for a high degree of integration.

FIG. 1 is a cross-sectional view illustrating a conventional NAND-type flash memory cell. Referring to FIG. 1, a unit cell of the NAND-type flash memory can include a gate structure including a floating gate 14 and a control gate 18 that is vertically stacked on a semiconductor substrate 10.

A tunnel dielectric layer 12 is formed on the substrate 10, and the floating gate 14 is formed on the tunnel dielectric layer 12. A dielectric interlayer 16 is formed on the floating gate 14, and the control gate 18 is formed on the dielectric interlayer 16. Accordingly, the tunnel dielectric layer 12, the floating gate 14, the dielectric interlayer 16 and the control gate 18 are vertically stacked on the substrate 10, thereby forming the stacked gate structure on the substrate 10. Source/drain regions 20 are formed at surface portions of the substrate 10 close to the gate structure of a cell transistor of the NAND type flash memory.

The floating gate 14 serves as a tunneling source during programming/erasing data into/from the unit cell. For that reason, the floating gate 14 can include in-situ doped polysilicon in which the uniformity of impurity doping can be good and a resistance may be relatively easy to control. The dielectric interlayer 16 holds electric charges inside the floating gate 14 and typically includes an oxide-nitride-oxide (ONO) layer.

An operation voltage is applied to the control gate 18, so that electrons move from the substrate 10 to the floating gate 14 in programming data into the flash memory device and electrons move from the floating gate 14 to the substrate 10 in erasing data from the flash memory device. Accordingly, the control gate 14 can have a low electrical resistance, and is usually formed into a stacked structure in which a polysilicon layer and a metal/metal silicide layer are vertically stacked on the dielectric interlayer 16 to reduce an electrical resistance thereof. However, the conventional NAND-type flash memory device having the above stacked gate structure may have problems in that a threshold voltage Vth of a unit cell of the flash memory may vary as the design rule of the semiconductor device is reduced.

In particular, when the design rule is reduced to less than about 0.12 μm, an interval between neighboring gate structures in a cell area may be so small that a parasitic capacitance Cs due to a capacitive coupling may be generated between floating gates in the neighboring gate structures. The capacitive coupling between the floating gates may cause the variation of the threshold voltage (Vth) in a specific cell of the flash memory device. For example, when data is programmed into a cell, the threshold voltage of a cell adjacent to the programmed cell increases, and in contrast, when data is erased from a cell, the threshold voltage of a cell adjacent to the erased cell decreases.

A capacitance C of a capacitor is generally expressed by the following equation (1):
C=εA/d (1)
In equation (1), ε denotes a dielectric constant of a dielectric layer, and A and d respectively denote a surface area and a thickness of the dielectric layer for the capacitor. As noted from equation (1), a parasitic capacitance (Cs) of a capacitor decreases as the dielectric constant of a dielectric layer for the capacitor is decreased and the surface area of the dielectric layer is reduced. Accordingly, a low dielectric gate spacer can be formed on the substrate 10 between cells in the flash memory device. The floating gate 14 can be formed to a small thickness to thereby decrease an effective area of the dielectric layer.

In some conventional methods, an in-situ doped amorphous silicon layer can be deposited by a chemical vapor deposition (CVD) process using source gases of silane (SiH₄) gas and phosphine (PH₃) gas at a temperature of about 500° C. to about 550° C. Then, a heat treatment process may be performed on the amorphous silicon layer to thereby form the floating gate comprising P-doped polysilicon.

An experiment was conducted on a conventional floating gate for measuring a concentration of phosphorus (P) in the conventional floating gate with respect to a thickness thereof. An annealing process was performed on the floating gate comprising P-doped polysilicon at a temperature of about 800° C. for thirty minutes. A concentration of phosphorus (P) in the conventional floating gate comprising P-doped polysilicon was measured with respect to a thickness of the conventional floating gate. Table 1 shows results of the above experiment on the conventional floating gate.

TABLE 1

| Thickness of the | Concentration of the |
|---|---|
| floating gate (Å) | phosphorus (P) (atom/cm³) |
| 100 | 1.9E20 |
| 150 | 3.2E20 |
| 180 | 7.5E20 |

Table 1 indicates that the concentration of phosphorus (P) can decrease as the thickness of the floating gate is reduced. When a subsequent heat treatment is performed on the floating gate, phosphorus (P) in the floating gate may be diffused outwardly, and a total amount of the out-diffused phosphorus (P) is the same regardless of a thickness of the floating gate. Accordingly, the more the phosphorus (P) that may be diffused outwardly, the smaller the thickness of the floating gate may be. Therefore, the concentration of phosphorus (P) decreases in proportional to the thickness of the floating gate, as indicated in Table 1.

A low concentration of phosphorus (P) in the floating gate can cause a depletion region at a lower portion of the floating gate when an operation voltage is applied to the control gate. The depletion region at the bottom portion of the floating gate may cause an increase of an equivalent oxide thickness (EOT) of a gate dielectric layer (tunnel dielectric layer), thereby reducing an operation speed of the flash memory device.

### SUMMARY

Embodiments according to the invention can provide methods of forming floating gates in non-volatile memory devices including alternating layers of amorphous silicon and Atomic Layer Deposition (ALD) dopant layers and floating gates so formed. Pursuant to these embodiments, a method of forming a silicon layer on a substrate includes providing a silicon source gas to form an amorphous silicon layer on a substrate and providing a dopant source gas to adsorb dopants onto the amorphous silicon layer to form a dopant layer on a surface of the amorphous silicon layer.

In some embodiments according to the invention, providing a silicon source gas and providing a dopant source gas are alternatingly and repeatedly performed to form the silicon layer comprising a plurality of interspersed amorphous silicon and dopant layers. In some embodiments according to the invention, providing a dopant source gas includes providing the dopant source gas at a temperature of about 450 degrees Centigrade to about 500 degrees Centigrade.

In some embodiments according to the invention, providing a silicon source gas includes providing the silicon source gas at a temperature of about 450 degrees Centigrade to about 500 degrees Centigrade. In some embodiments according to the invention, the silicon layer includes an average dopant concentration greater than about 6×10²⁰ impurities/cm³. In some embodiments according to the invention, the silicon layer includes an average dopant concentration of about 1×10²¹ impurities/cm³.

In some embodiments according to the invention, providing a dopant source gas includes providing the dopant source gas to form more than two atomic layers of the dopant on the amorphous silicon layer. In some embodiments according to the invention, providing a silicon source gas further includes providing the silicon source gas at a temperature of about 500 degrees Centigrade to about 550 degrees Centigrade and providing a first dopant source gas at about 500 degrees Centigrade to about 550 degrees Centigrade before providing the dopant source gas to provide a first dopant layer beneath the dopant layer. In some embodiments according to the invention, the method further includes cooling the substrate to a temperature of about 450 degrees Centigrade to about 500 degrees Centigrade before providing the dopant source gas.

In some embodiments according to the invention, providing the silicon source gas includes providing a silane source gas at a rate of about 500 sccm to about 2000 sccm for about 30 minutes to about 60 minutes to form the amorphous silicon layer to a thickness of about 10 Angstroms to about 30 Angstroms. Providing the dopant source gas includes providing a phosphine gas at a rate of about 500 sccm to about 2000 sccm for about 60 minutes to about 90 minutes to form the dopant layer to 2 or 3 atomic layers of the dopant.

In some embodiments according to the invention a NAND-type non-volatile memory device includes a tunnel dielectric layer on a substrate and a multi-layered U-shaped floating gate on the tunnel dielectric layer. A dielectric interlayer is on the multi-layered U-shaped floating gate and a control gate is on the dielectric interlayer.

### BRIEF DESCRIPTION OF THE DRAWINGS

FIG. 1 is a cross-sectional view illustrating conventional NAND-type flash memory cells;

FIG. 2 is a cross-sectional view illustrating a heavily doped silicon thin layer in some embodiment according to the present invention.

FIGS. 3A to 3E are cross-sectional views illustrating methods of forming a NAND-type flash memory device in some embodiment according to the present invention.

### DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

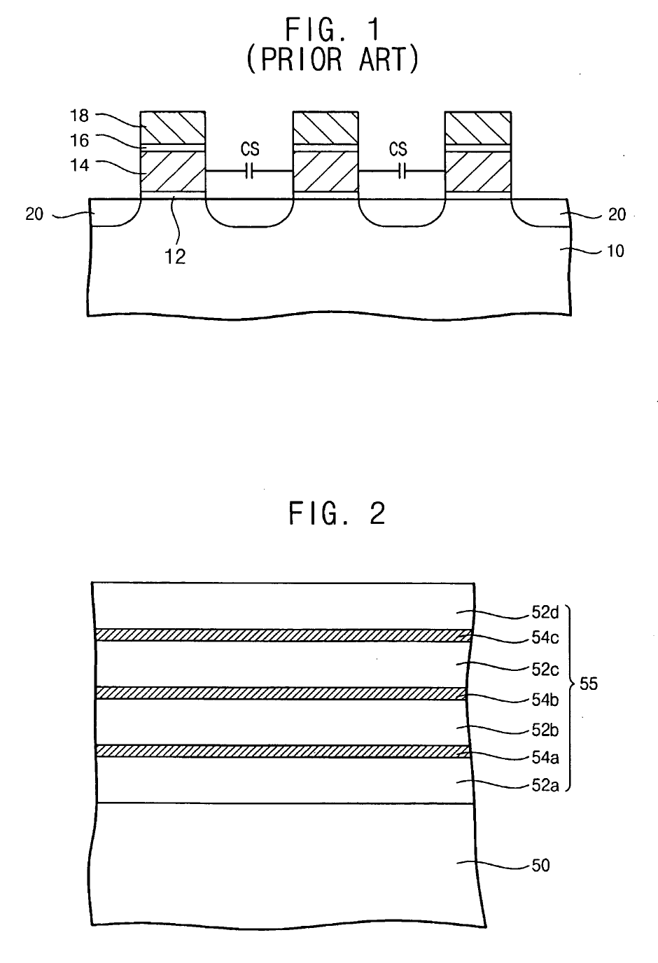

FIG. 2 is a cross-sectional view illustrating a heavily doped silicon thin layer in accordance with an example embodiment of the present invention. Referring to FIG. 2, a heavily doped silicon thin layer 55 of an example embodiment of the present invention has a multi-layered structure where a plurality of silicon layers 52a, 52b, 52c and 52d and a plurality of dopant layers 54a, 54b and 54c are alternately stacked on a substrate. More or fewer layers may be used.

Each of the silicon layers 52a, 52b, 52c and 52d may be formed by a chemical vapor deposition (LPCVD) process using a silicon source gas such as silane (SiH₄), dichlorosilane (SiH₂Cl₂), disilane (Si₂H₆) or hexachlorodisilane (Si₂Cl₆). In some embodiments according to the invention, each of the silicon layers 52a, 52b, 52c and 52d is formed by a low pressure CVD (LPCVD) process using silane (SiH₄) gas.

Each of the silicon layers 52a, 52b, 52c and 52d is deposited as an amorphous phase. In some embodiments of the present invention, a first silicon layer 52a that is formed first among the above silicon layers 52a, 52b, 52c and 52d may be formed at a temperature of about 500° C. to about 600° C. so as to increase the deposition rate, whereas the other silicon layers 52b, 52c and 52d are formed on the first silicon layer 52a at temperature of about 450° C. to about 500° C. (i.e., lower than that of the first silicon layer 52a).

Each of the dopant layers 54a, 54b and 54c may be formed by an atomic-layer doping process using an LPCVD process. In other words, when each of the silicon layers 52a, 52b, 52c and 52d is exposed to a dopant source gas such as phosphine (PH₃) gas or arsine (AsH₃) gas, dopants are adsorbed onto a surface of each of the silicon layers 52a, 52b, 52c and 52d by an atom of the dopants, thereby forming an atomic layer on each of the silicon layers 52a, 52b, 52c and 52d as the dopants layers 54a, 54b and 54c.

In some embodiments of the present invention, a phosphine (PH3) gas is supplied onto a surface of each silicon layers 52a, 52b, 52c and 52d at a temperature of about 450° C. to about 500° C., and phosphorus (P) is adsorbed into the surface of each silicon layers 52a, 52b, 52c and 52d, thereby forming two or three atomic layers of phosphorus (P) on the surface of each of the silicon layers 52a, 52b, 52c and 52d. That is, each of the dopant layers 54a, 54b and 54c including two or three atomic layers is formed on the silicon layers 52a, 52b, 52c and 52d, respectively.

Accordingly, a silicon layer 55 having a multilayered structure in which a silicon (Si) layer and a phosphorus (P) layer are alternately formed on the substrate by alternately supplying a silane (SiH₄) gas and a phosphine (PH₃) gas in an LPCVD process.

In contrast to embodiments according to the invention, conventional heavily P-doped silicon thin layers can be formed by a selective epitaxial process using silane (SiH₄) gas and phosphine (PH₃) gas, so that the silicon thin layer is formed by a growth process simultaneously with a crystallization process. Accordingly, the concentration of phosphorus (P) in the silicon thin layer may be less than a solid solution limit of silicon. That is, the average concentration of phosphorus (P) in the conventional silicon thin layer may be limited to approximately 6×10²⁰/cm³.

On the contrary, in some embodiments according to the invention, the heavily P-doped silicon thin layer 55 of the present embodiment may be formed by an LPCVD process using a silane (SiH₄) gas and a phosphine (PH₃) gas that are alternately provided to a processing chamber, so that the silicon thin layer 55 is formed by a deposition process for an amorphous silicon layer and a heat treatment to the amorphous silicon layer. Accordingly, phosphorus (P) may be heavily doped into the silicon thin layer at a concentration that exceeds the solid solution limit of silicon. That is, the average concentration of phosphorus (P) in the silicon thin layer of some embodiments can be approximately 1×10²¹/cm³, thereby forming the heavily P-doped silicon thin layer 55 on a substrate 50.

According to the example embodiment of the present invention, the heavily P-doped silicon thin layer 55 may be formed on a substrate at a concentration of phosphorus (P) that is five to ten times higher than that of the conventional silicon thin layer by coating an in-situ doped amorphous silicon thin layer on the substrate at first through a deposition process using a silane (SiH₄) gas and a phosphine (PH₃) gas at a temperature of about 500° C. to about 550° C.

Hereinafter, a method of forming the above heavily P-doped silicon thin layer 55 will be described in detail with reference to FIG. 2. A semiconductor substrate 50 including an insulating layer (not shown) such as a silicon oxide layer is loaded into a processing chamber of an LPCVD system. Then, an inside of the chamber is kept at a pressure of about 30 pa to about 200 pa.

The substrate 50 is heated to a temperature of about 500° C. to about 550° C. and then, a silicon source gas, such as a silane (SiH₄) gas, is provided at about 500 standard cubic centimeter per minute (sccm) to about 2000 sccm, to the processing chamber through a silicon source gas line for about 30 min to about 60 min. Thus, a first silicon layer 52a comprising amorphous silicon is formed on the substrate 50 to a thickness of about 10 Å to about 30 Å due to a thermal decomposition of silane (SiH₄) gas. An overall decomposition reaction of the silane (SiH4) gas is generally expressed as the following equation (2):
SiH₄(vapor)=Si(solid)+2H₂(gas) (2)

Thereafter, the silicon source gas line is closed and the substrate 50 is cooled down to a temperature of about 450° C. to about 500° C. A dopant source gas, such as a phosphine (PH₃) gas, at about 500 sccm to about 2000 sccm, is supplied to the processing chamber through a dopant source gas line for about 60 min to about 90 min. As a result, a first dopant layer 54a including two or three atomic layers of phosphorus (P) is adsorbed onto the first silicon layer 52a.

Then, the dopant source gas line is closed, and a silicon source gas, such as a silane (SiH₄) gas at about 500 sccm to about 2000 sccm, is again supplied into the processing chamber through the silicon source gas line for about 30 min to 60 min while the substrate 50 is kept at a temperature of about 450° C. to about 500° C. As a result, a second silicon layer 52b including amorphous silicon is formed on the first silicon layer 52a including the first doping layer 54a to a thickness of about 10 Å to about 30 Å.

Alternately repeating the above steps of supplying silane (SiH4) gas and of supplying phosphine gas (PH4) at least once at a low temperature of about 450° C. to about 500° C. generates the silicon thin layer 55 having a multilayered structure in which a plurality of the silicon layers 52a, 52b, 52c and 52d and a plurality of the dopant layers 54a, 54b and 54c are alternately stacked on the substrate 50.

Thereafter, the substrate 50 on which the heavily P-doped silicon thin layer 55 having a predetermined thickness is unloaded from the processing chamber of the LPCVD system.

In some embodiments according to the invention, including a multi-layered silicon thin layer 55, the dopants layers of phosphorus (P) 54a, 54b and 54c are interposed between the silicon layers 52a, 52b, 52c and 52d, to reduce the out-diffusion of the dopants during a subsequent heat treatment process.

Further, the silicon thin layer 55 is heavily doped with phosphorus (P) at an average concentration of about 1×10²¹/cm³ beyond a solid solution limit of silicon, so that the high concentration of the dopants may sufficiently compensate for an amount of the dopants outwardly diffused from the silicon thin layer in a subsequent heat treatment. Accordingly, the silicon thin layer may have a higher concentration of the dopants despite the subsequent heat treatment.

In general, as appreciated by the present inventors, when a doped silicon thin layer is formed at a relatively high deposition temperature, the concentration of the dopants in the silicon thin layer may be generally reduced. However, in some embodiments according to the invention the heavily doped silicon thin layer 55 is formed on the substrate at a relatively low deposition temperature ranged from about 450° C. to about 500° C., thereby minimizing the decrease in the dopant concentration of the silicon thin layer 55.

When the silicon thin layer 55 is formed on an insulation layer (such as an oxide layer) at the same deposition temperature of about 450° C. to about 550° C., a deposition rate of the silicon thin layer 55 can be lower than when formed on the substrate 50, so that the formation of a multi-layered silicon thin layer (at the same deposition temperature of about 450° C. to about 550° C.) may call for a relatively long processing time. For that reason, in some embodiments according to the invention, the first silicon layer 52a is formed on the substrate 50 at a deposition temperature of about 500° C. to about 600° C., whereas the remaining silicon thin layers 52b, 52c and 52d are formed on the first silicon thin layer 52a at a deposition temperature ranged from about 450° C. to about 550° C.

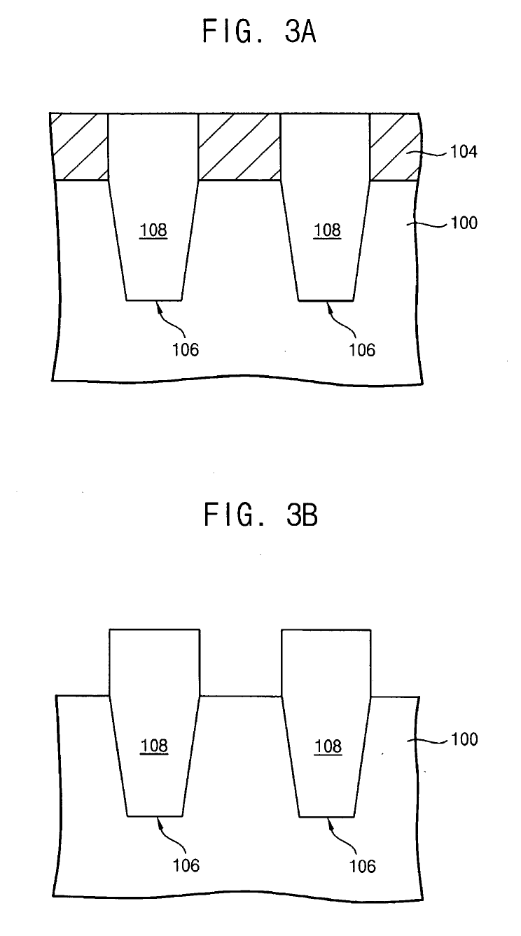

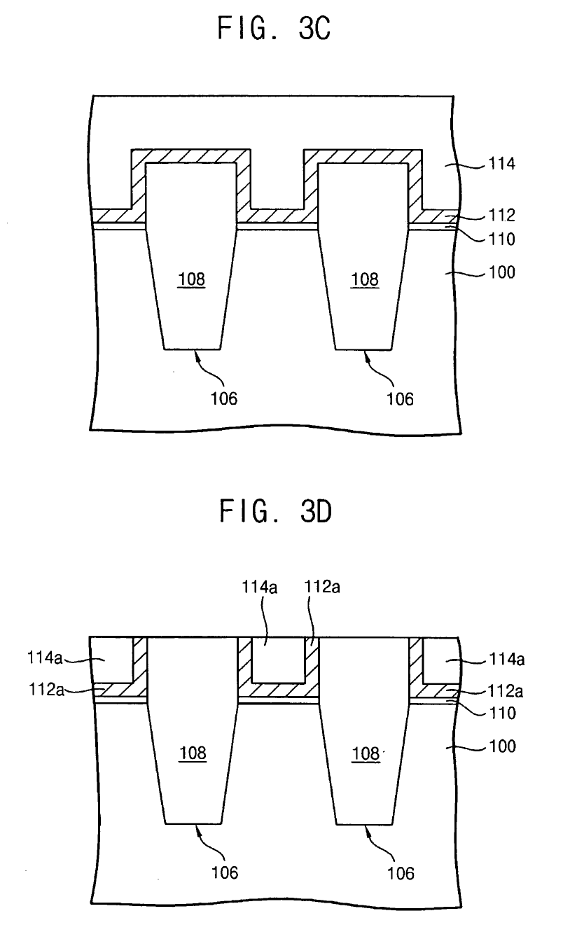

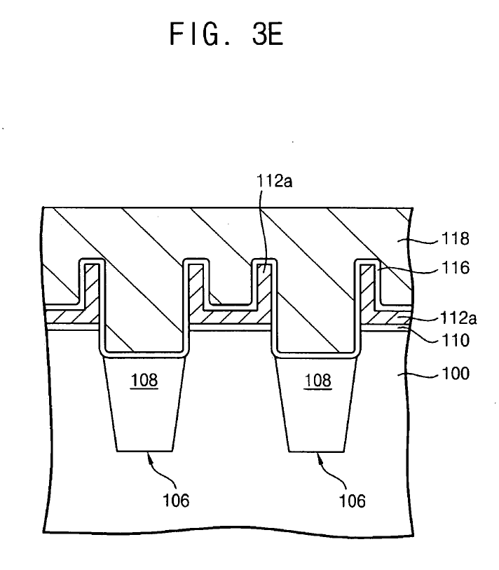

Hereinafter, a method of manufacturing a semiconductor device including the above heavily P-doped silicon thin layer described in detail with reference to FIGS. 3A to 3E. As an example embodiment of the semiconductor device including the above heavily P-doped silicon thin layer, a NAND-type flash memory device having a unit cell where a tunnel dielectric layer, a floating gate, a dielectric interlayer and a control gate are sequentially stacked on a substrate is disclosed hereinafter. When programming data into the NAND flash memory device, a positive voltage is applied to the control gate and is coupled to the floating gate, thereby moving electrons from the substrate into the floating gate due to a Fowler-Nordheim (F-N) tunneling or a hot carrier injection.

On the contrary, when erasing data from the NAND flash memory device, a negative voltage is applied to the control gate and electrons in the floating gate moves to the substrate, thereby discharging electrons from the floating gate.

In the above programming operation mode of the NAND flash memory device, a ratio of a voltage applied to the control gate with respect to a voltage coupled to the floating gate is defined as a coupling ratio C/R of the flash memory device. In general, the higher the coupling ratio C/R is, the better the speed and performance of the flash memory device is. The coupling ratio C/R is expressed by the following equation (3).
C/R═C_{ONO}/(C_{ONO}+Cₜᵤₙ) (3)

In equation (3), C_{ONO} denotes a capacitance of a dielectric interlayer between the floating gate and the control gate and Cₜᵤₙ denotes a capacitance of the tunnel dielectric layer.

As noted from equation (3), a value of C_{ONO}/Cₜᵤₙ needs to be increased as much as possible so as to increase the coupling ratio C/R. Accordingly, the dielectric interlayer needs to be formed to a thickness as small as possible and to have a surface area as large as possible so as to increase the capacitance C_{ONO} of the dielectric interlayer. However, since a small thickness of the dielectric interlayer causes a current leakage, an effective surface area of the dielectric interlayer is enlarged so as to increase the capacitance C_{ONO} of the dielectric interlayer. In some of the present embodiments, a surface area of floating gate is enlarged so as to increase the capacitance C_{ONO} of the dielectric interlayer.

In addition, the floating gate needs to be formed to a thickness as small as possible so as to reduce the parasitic capacitance between the unit cells of the flash memory device. However, the small thickness of the floating gate reduces the coupling ratio of the flash memory device, thereby decreasing operation speed and performance of the flash memory device.

For that reason, the floating gate is formed to a thickness of no more than about 100 Å with a plurality of bulgy and hollow shapes, so that the surface area of the floating gate is sufficiently increased. Accordingly, the floating gate has a high coupling ratio with a sufficiently small thickness, thereby reducing the parasitic capacitance between neighboring unit cells of the flash memory device. FIGS. 3A to 3E are cross-sectional views illustrating a method of manufacturing a NAND-type flash memory device according to an example embodiment of the present invention.

FIG. 3A illustrates a processing step of forming a field oxide layer 108 on a semiconductor substrate 100. Referring to FIG. 3A, a pad oxide layer 102 and a pad nitride layer 104 are sequentially formed on the substrate 100 such as a silicon wafer, and then are partially removed from the substrate 100 by a photolithography process, thereby forming a hard mask pattern on the substrate 100. The substrate 100 is partially exposed through the hard mask pattern.

The substrate 100 is anisotropically etched away using the hard mask pattern as an etching mask to a predetermined depth, thereby forming a trench 106 on the substrate 100. The trench 106 is filled with a field oxide layer in a subsequent process.

A portion of the substrate 100 exposed through the trench 106 is subjected to a thermal treatment in an oxidation atmosphere for curing silicon damages caused by a high energy ion impact in the etching process for forming the trench 106. As a result, silicon in the substrate 100 is reacted with oxygen and an oxide layer (not shown) is formed along a sidewall and a bottom surface of the trench 106.

Then, a gap-fill oxide layer having good gap filling characteristics such as undoped silicate glass (USG) and high density plasma (HDP) is formed on a resultant structure including the hard mask pattern to a sufficient thickness to fill up the trench 106. The gap-fill oxide layer may be formed by a chemical vapor deposition (CVD) process, a plasma-enhanced chemical vapor deposition (PECVD) process or a high density plasma-chemical vapor deposition (HDP-CVD) process. The gap-fill oxide layer then is removed from the resultant structure by a chemical mechanical polishing (CMP) process or an etch-back process until an upper surface of the hard mask pattern is exposed. As a result, the gap-fill oxide layer remains only in the trench 106, thereby forming the field oxide layer 108 in the trench 106. The substrate 100 is then defined into active regions in which a plurality of conductive structures is formed and field regions by which the active regions are electrically isolated from each other.

Referring to FIG. 3B, the hard mask pattern is removed from the substrate 100. In particular, the pad nitride layer 104 is removed from the pad oxide layer 102 by a stripping process using a phosphoric acid solution. Then, the pad oxide layer 102 is removed from the substrate 100 by a wet etching process.

FIG. 3C illustrates a processing step of forming a tunnel dielectric layer 110, a floating gate layer 112 and a sacrificial layer 114 on the substrate 100 including the field oxide layer 108. Referring to FIG. 3C, a cleaning process is performed on the substrate 100 including the field oxide layer 108, and a tunnel dielectric layer (i.e., a gate dielectric layer) 110 is formed on a surface of the substrate 100 in the active region. For example, the tunnel dielectric layer comprises silicon oxide, silicon oxynitride, a material having a dielectric constant higher than silicon oxide and silicon oxynitride (which widely known as high-k material), etc. The tunnel dielectric layer 110 may be formed by any suitable methods known in the art, such as CVD, PECVD, HDP-CVD and atomic layer deposition (ALD).

A floating gate layer 112 into which an N-type dopant including phosphorus (P) is heavily doped, is formed on the tunnel dielectric layer 110 and the field oxide layer 108. In some embodiments according to the invention, the floating gate layer 112 may be deposited to a thickness of no more than about 100 Å by LPCVD.

The substrate 100 including the tunnel dielectric layer 110 is loaded into a processing chamber of an LPCVD system, and an inside of the processing chamber is kept at a pressure of about 30 pa to about 200 pa. The substrate 100 is heated to a temperature of about 500° C. to about 600° C. and then, a silicon source gas such as silane (SiH₄), dichlorosilane (SiH₂Cl₂), disilane (Si₂H₆) or hexachlorodisilane (Si₂Cl₆) is supplied into the processing chamber through a silicon source gas line. In some embodiments according to the present invention, SiH₄ gas is provided at about 500 sccm to about 2000 sccm to the processing chamber for about 30 min to about 60 min, and SiH4 gas is thermally decomposed due to a heat of the substrate 100. Accordingly, a first amorphous silicon layer is formed on the substrate 100 to a thickness of about 10 Å to about 30 Å.

Thereafter, the silicon source gas line is closed and the substrate 100 is cooled to a temperature of about 450° C. to about 500° C. A dopant source gas including dopants for doping the silicon layer with N-type dopants, such as phosphine (PH₃) gas and arsine (AsH₃) gas, is supplied to the processing chamber through a dopant source gas line. In some embodiments according to the present invention, PH₃ gas of about 500 sccm to about 2000 sccm may be supplied for about 60 min to 90 min, and phosphorus (P) is repeatedly adsorbed onto a surface of the amorphous silicon layer. Accordingly, a plurality of atomic layers, such as two or three atomic layers, are formed on the first amorphous silicon layer.

Then, the dopant source gas line is closed, and a silicon source gas, for example, SiH₄ gas of about 500 sccm to about 2000 sccm, is again supplied into the processing chamber for about 30 to about 60 minutes through the silicon source gas line on the condition that the substrate 100 is kept at temperature of abut 450° C. to about 500° C. As a result, a second amorphous silicon layer is formed on the first amorphous silicon layer and on the atomic layers to thickness of about 10 Å to about 30 Å.

Alternately repeating the above steps of supplying silane (SiH4) gas and of supplying phosphine gas (PH3) about three or four times at a low temperature of about 450° C. to about 500° C. generates a heavily multi-layered P-doped silicon thin layer having a thickness of about less than about 100 Å. Accordingly, the heavily P-doped silicon thin layer is formed into a multilayered structure in which a plurality of the silicon layers and a plurality of the dopant layers are alternately stacked on the substrate 100 as the floating gate 112.

Thereafter, the substrate 100 including the floating gate 112 is unloaded from the processing chamber of the LPCVD system. Another oxide layer having a good gap filling characteristic such as an undoped silicate glass (USG) layer is formed on the floating gate layer 112 to a sufficient thickness to fill the intervals between the field oxide layers 108, thereby forming a sacrificial layer 114 on the substrate 100. The sacrificial layer 114 may be formed by any suitable method known in the art, such as a CVD process.

FIG. 3D illustrates a processing step of forming a floating gate pattern 112a on the substrate 100. Referring to FIG. 3D, the sacrificial layer 114 on the floating gate layer 112 is planarized until a top surface of the floating gate layer 112 is exposed. The sacrificial layer 114 may be removed by a chemical mechanical polishing (CMP) process or an etch-back process.

Subsequently, the floating gate layer 112 is removed from above the field oxide layer 108 and planarized by a CMP process or an etch-back process until a top surface of the field oxide layer 108 is exposed, so that only the sacrificial layer 114 and the floating gate layer 112 remain on the substrate 100 between the field oxide layers 108. That is, only the sacrificial layer 104 and the floating gate layer 112 remain on the active region of the substrate 100 by a unit cell of the flash memory device. Accordingly, the floating gate layer 112 and the sacrificial layer 114 are separated to form a floating gate layer pattern 112a having a bulgy and hollow shape and a sacrificial pattern 114a by a unit cell of the flash memory device. FIG. 3E illustrates a processing step of forming a dielectric interlayer 116 and a control gate 118 on a resultant structure including the floating gate pattern 112a. Referring to FIG. 3E, the sacrificial pattern 114a is removed from the substrate 100 by a wet etching process. When the wet etching process is performed to remove the sacrificial pattern 114a, the field oxide layer 108 is also etched to a predetermined depth below a top surface of the substrate 100, so that an outer sidewall of the floating gate pattern 112a is exposed.

A dielectric interlayer 116 such as an oxide/nitride/oxide (ONO) layer is formed on a surface of the resultant structure including the floating gate pattern 112a. A floating gate and a control gate in the flash memory device are isolated from each other by the dielectric interlayer 116 in a subsequent process. Accordingly, the dielectric interlayer 116 is formed even on the outer sidewall of the floating gate pattern 112a, so that an effective area of the dielectric interlayer 116 is quietly enlarged, thereby sufficiently increasing the coupling ratio of the flash memory device. The interlayer dielectric layer 116 may be formed by a thermal oxidation process or an LPCVD process.

Subsequently, a control gate layer 118 is formed on the interlayer dielectric layer 116. The control gate layer 118 is typically formed into a multilayered structure in which a polysilicon layer heavily doped with N-type dopants and a metal layer or a metal silicide layer are stacked on the dielectric interlayer 116.

The control gate layer 118, the dielectric interlayer 116 and the floating gate pattern 112a are sequentially etched by a self-aligned gate etching process, thereby forming a stacked gate structure for a unit cell of the NAND-type flash memory device.

In a method of manufacturing a NAND-type flash memory device of the present invention, the floating gate has a prominence and depression shaped (e.g., U-shaped), thereby increasing a surface area thereof. Accordingly, an effective surface area of the dielectric interlayer formed on the floating gate is also enlarged as the surface area of the floating gate is enlarged as large as the surface area of the prominence and depression portions of the floating gate, thereby increasing the capacitance (C_{ONO}) between the floating gate and the control gate and the coupling ratio of the flash memory device.

Further, the floating gate is formed to a small thickness of no more than about 100 Å to thereby reduce the parasitic capacitance between the memory cells.

Furthermore, the floating gate is heavily doped with phosphorus (P) at an average concentration beyond the solid solution limit of silicon, so that the high concentration of the dopants may sufficiently compensate for an amount of the dopants outwardly diffused from the floating gate in a heat treatment process. Accordingly, the floating gate may have a high concentration of the dopants despite of the subsequent heat treatment.

According to the present invention as described above, alternately repeating the steps of supplying silane (SiH4) gas and of supplying phosphine gas (PH3) generates a heavily P-doped silicon thin layer having a small thickness. Accordingly, the heavily P-doped silicon thin layer is formed into a multilayer structure in which a plurality of the silicon layers and a plurality of the dopant layers are alternately stacked on the substrate. Further, the silicon thin layer is heavily doped with phosphorus (P) at an average concentration beyond the solid solution limit of silicon, so that the high concentration of the dopants may sufficiently compensate for an amount of the dopants outwardly diffused from the floating gate in a heat treatment process. Accordingly, the silicon thin layer may have a high concentration of the dopants despite of the subsequent heat treatment.

In case that the silicon thin layer heavily doped with dopants is used for a floating gate of a non-volatile memory device such as a flash memory device, a depletion region is prevented at a bottom portion of the floating gate, thereby improving an operating speed of the non-volatile memory device.

Although some embodiments of the present invention have been described, it is understood that the present invention should not be limited to these some embodiments but various changes and modifications can be made by one skilled in the art within the spirit and scope of the present invention as hereinafter claimed.

What is claimed:

1. A method of forming a silicon thin layer on a substrate, comprising:
loading the substrate into a chamber;
forming an amorphous silicon layer on the substrate by supplying a silicon source gas into the chamber;
adsorbing dopants onto the amorphous silicon layer by supplying a dopant source gas into the chamber, thereby forming a dopant layer at surface portions of the amorphous silicon layer; and
repeating the step of forming the amorphous silicon layer and the step of adsorbing dopants onto the amorphous silicon layer, thereby forming the silicon thin layer including a plurality of silicon layers and a plurality of dopant layers.

2. The method of claim 1, wherein the silicon source gas includes any one selected from the group consisting of silane (SiH₄), dichlorosilane (SiH₂Cl₂), disilane (Si₂H₆), hexachlorodisilane (Si₂Cl₆) and a combination thereof.

3. The method of claim 1, wherein the dopant source gas includes any one selected from the group consisting of phosphine (PH₃), arsine (AsH₃) and a combination thereof.

4. The method of claim 1, wherein repeating the step of forming the amorphous silicon layer includes a first deposition process performed at a first temperature ranged from about 500° C. to about 600° C. and a second deposition process performed after the first deposition process is completed at a second temperature ranged from about 450° C. to about 500° C.

5. The method of claim 1, wherein adsorbing the dopants onto the amorphous silicon layer is carried out at a temperature of about 450° C. to about 500° C.

6. The method of claim 1, wherein the chamber includes a processing chamber of a low pressure chemical vapor deposition (LPCVD) system.

7. A method of manufacturing a non-volatile memory device, comprising:
forming a tunnel dielectric layer on a semiconductor substrate on which an active region and a field region are defined;
forming a floating gate on the tunnel dielectric layer, the floating gate including a plurality of silicon layers and a plurality of dopant layers formed by repeating a step of forming an amorphous silicon layer by supplying a silicon source gas and a step of forming a dopant layer on the amorphous silicon layer by adsorbing dopants onto the amorphous silicon layer;
forming a dielectric interlayer on the floating gate; and
forming a control gate on the dielectric interlayer.

8. The method of claim 7, wherein the floating gate is formed by a low pressure chemical vapor (LPCVD) process.

9. The method of claim 7, wherein the silicon source gas includes any one selected from the group consisting of silane (SiH₄), dichlorosilane (SiH₂Cl₂), disilane (Si₂H₆), hexachlorodisilane (Si₂Cl₆) and a combination thereof.

10. The method of claim 7, wherein the dopant source gas includes any one selected form the group consisting of phosphine (PH₃), arsine (AsH₃) and a combination thereof.

11. The method of claim 7, wherein forming the floating gate includes a first deposition process performed at a first temperature ranged from about 500° C. to about 600° C. and a second deposition process performed after the first deposition process is completed at a second temperature ranged from about 450° C. to about 500° C.

12. The method of claim 7, wherein adsorbing the dopants onto the amorphous silicon layer is carried out at a temperature of about 450° C. to about 500° C.

13. The method of claim 7, wherein the floating gate is formed into a prominence and depression shape.

14. The method of claim 13, wherein forming the floating gate includes:
forming a floating gate layer on the tunnel dielectric layer in the active region and on a device isolation layer in the field region, the device isolation layer electrically separating the active regions from each other;
forming a sacrificial layer on the floating gate layer;
removing the sacrificial layer from the substrate until a top surface of the floating gate layer is exposed;
removing the floating gate layer from the substrate until a top surface of the device isolation layer is exposed, so that the floating gate layer and the sacrificial layer remain only on the substrate of the active region to thereby form a floating gate pattern and a sacrificial pattern by a unit cell of the non-volatile memory device; and
removing the sacrificial pattern from the substrate.

15. The method of claim 14, wherein the sacrificial layer comprises an oxide.

16. The method of claim 14, wherein the device isolation layer is removed to a predetermined depth from a surface of the substrate simultaneously with the sacrificial pattern, so that an outer sidewall of the floating gate pattern is exposed.

17. A method of forming a silicon layer on a substrate comprising:
providing a silicon source gas to form an amorphous silicon layer on a substrate; and
providing a dopant source gas to adsorb dopants onto the amorphous silicon layer to form a dopant layer on a surface of the amorphous silicon layer.

18. A method according to claim 17 wherein providing a silicon source gas and providing a dopant source gas are alternatingly and repeatedly performed to form the silicon layer comprising a plurality of interspersed amorphous silicon and dopant layers.

19. A method according to claim 17 wherein providing a dopant source gas comprises providing the dopant source gas at a temperature of about 450 degrees Centigrade to about 500 degrees Centigrade.

20. A method according to claim 17 wherein providing a silicon source gas comprises providing the silicon source gas at a temperature of about 450 degrees Centigrade to about 500 degrees Centigrade.

21. A method according to claim 20 wherein the silicon layer comprises an average dopant concentration greater than about 6×10²⁰ impurities/cm³.

22. A method according to claim 20 wherein the silicon layer comprises an average dopant concentration of about 1×10²¹ impurities/cm³.

23. A method according to claim 17 wherein providing a dopant source gas comprises providing the dopant source gas to form more than two atomic layers of the dopant on the amorphous silicon layer.

24. A method according to claim 17 wherein providing a silicon source gas further comprises:
providing the silicon source gas at a temperature of about 500 degrees Centigrade to about 550 degrees Centigrade; and
providing a first dopant source gas at about 500 degrees Centigrade to about 550 degrees Centigrade before providing the dopant source gas to provide a first dopant layer beneath the dopant layer.

25. A method according to claim 24 further comprising:
cooling the substrate to a temperature of about 450 degrees Centigrade to about 500 degrees Centigrade before providing the dopant source gas.

26. A method according to claim 25 wherein providing the silicon source gas comprises providing a silane source gas at a rate of about 500 sccm to about 2000 sccm for about 30 minutes to about 60 minutes to form the amorphous silicon layer to a thickness of about 10 Angstroms to about 30 Angstroms; and
wherein providing the dopant source gas comprises providing a phosphine gas at a rate of about 500 sccm to about 2000 sccm for about 60 minutes to about 90 minutes to form the dopant layer to 2 or 3 atomic layers of the dopant.

27. A NAND-type non-volatile memory device comprising:
a tunnel dielectric layer on a substrate;
a multi-layered U-shaped floating gate on the tunnel dielectric layer;
a dielectric interlayer on the multi-layered U-shaped floating gate; and
a control gate on the dielectric interlayer.

28. A NAND-type non-volatile memory device according to claim 27 wherein the multi-layered U-shaped floating gate comprises a plurality of interspersed amorphous silicon and dopant layers.

29. A NAND-type non-volatile memory device according to claim 28 wherein the multi-layered U-shaped floating gate comprises an average dopant concentration greater than about 6×10²⁰ impurities/cm³.
